(19) United States
(12) Patent Application Publication
(10) Pub. No.: US 2017/0179000 A1
(43) Pub. Date: Jun. 22, 2017

(54) THERMOELECTRIC COOLER HAVING A SOLDERLESS ELECTRODE

(71) Applicant: Intel Corporation, Santa Clara, CA (US)

(72) Inventors: Chandra Mohan JHA, Tempe, AZ (US); Kelly Porter LOFGREEN, Phoenix, AZ (US)

(21) Appl. No.: 14/975,247

(22) Filed: Dec. 18, 2015

(51) Int. Cl. H01L 23/38; H01L 35/34; H01L 23/367; H01L 35/08; H01L 35/32

(52) U.S. Cl. CPC H01L 23/38; H01L 35/08; H01L 35/32; H01L 23/3675; H01L 35/34

(57) ABSTRACT

Thermoelectric coolers having solderless electrical interconnects, and semiconductor packages incorporating such thermoelectric coolers, are described. In an example, a thermoelectric cooler includes a solderless electrode electrically connecting a P-type semiconductor column to an N-type semiconductor column, and the solderless electrode is in direct contact with diffusion barrier layers separating the solderless electrode from the P-type and N-type semiconductor material layers of the semiconductor columns. Methods of manufacturing thermoelectric coolers having solderless electrical interconnects are also described.

### TECHNICAL FIELD

Embodiments of the invention are in the field of semiconductor packages and, in particular, semiconductor packages including thermoelectric coolers having solderless electrical interconnects.

### BACKGROUND

Semiconductor packages are used for protecting an integrated circuit (IC) die, and also to provide the IC die with an electrical interface to external circuitry, e.g., a printed circuit board. Operations of the IC die generates heat that can lead to hot spots on the IC die within the semiconductor package, and such hot spots may be detrimental to operation of both the semiconductor package and an electronic product that incorporates the semiconductor package. Heat exchangers, such as heat spreaders, are used to transfer heat away from the IC die.

### BRIEF DESCRIPTION OF THE DRAWINGS

FIG. 1 illustrates a sectional view of a semiconductor package including thermoelectric coolers, in accordance with an embodiment.

FIG. 2 illustrates a thermoelectric cooler having interconnected P-N elements, in accordance with an embodiment.

FIG. 3 illustrates a sectional view of a P-N element of a thermoelectric cooler having solderless electrical interconnects, in accordance with an embodiment.

FIG. 4 illustrates a detail view, taken from FIG. 3, of a copper joint of a solderless electrode of a thermoelectric cooler, in accordance with an embodiment.

FIG. 5 illustrates a graph indicating cooling performances of various semiconductor package designs, in accordance with an embodiment.

FIG. 6 illustrates a method of manufacturing a semiconductor package including a thermoelectric cooler having a solderless electrical interconnect, in accordance with an embodiment.

FIGS. 7A-7E illustrate various operations in a method of manufacturing a semiconductor package including a thermoelectric cooler having a solderless electrical interconnect, in accordance with an embodiment.

FIG. 8 is a schematic of a computer system, in accordance with an embodiment.

### DESCRIPTION OF EMBODIMENTS

Semiconductor packages including thermoelectric coolers having solderless electrical interconnects, are described. In the following description, numerous specific details are set forth, such as packaging and interconnect architectures, in order to provide a thorough understanding of embodiments of the present invention. It will be apparent to one skilled in the art that embodiments of the present invention may be practiced without these specific details. In other instances, well-known features, such as specific semiconductor fabrication processes, are not described in detail in order to not unnecessarily obscure embodiments of the present invention. Furthermore, it is to be understood that the various embodiments shown in the Figures are illustrative representations and are not necessarily drawn to scale.

Existing heat spreaders provide generalized cooling of an overall mass of an integrated circuit (IC) die, however, heat spreaders do not provide localized cooling of hot spots on the IC die. Attempts to locally cool hot spots of an IC die using current-technology thermoelectric cooler devices have been unsuccessful due to the current-technology architecture. More particularly, the current-technology thermoelectric coolers utilize electrical interconnects that incorporate solder between N-type and P-type semiconductor layers. That is, current-technology thermoelectric coolers have been integrated in a semiconductor package through solder bonding, such that a solder alloy bonds the metallic diffusion barrier layers of the semiconductor columns to the copper interconnects that bridge between the N-type and P-type semiconductor columns. The solder bond is accompanied by high-parasitic loss and increased thermoelectric cooler thickness, which makes the current-technology thermoelectric coolers ineffective for cooling an IC die, e.g., a central processing unit (CPU) die. More particularly, it has been shown that current-technology thermal electric coolers have a thermal resistance that is too high to provide localized cooling of hot spots on the IC die.

By way of further background, attempts to eliminate solder bonds in thermoelectric coolers have relied on high-temperature diffusion bonding. Such bonding, however, has been shown to cause a loss of thermoelectric cooler functionality, rendering resulting thermoelectric coolers useless for incorporation within semiconductor packages. Accordingly, a need exists for a functional thermoelectric cooler having solderless electrical interconnects.

In an aspect, a thermoelectric cooler architecture eliminates solder bonds in the electrical interconnects. More particularly, the thermoelectric cooler may incorporate a solderless electrode having a bridge portion and a contact portion that are joined in a low temperature bonding process. The thermoelectric cooler architecture can reduce the overall thickness of the thermoelectric cooler by more than half as compared to current-technology thermoelectric coolers. For example, the thermoelectric cooler architecture may include a thickness of less than 50 microns, as compared to thicknesses of at least 100 microns for current-technology thermoelectric coolers. Furthermore, the solderless bond, e.g., a copper joint, of the solderless electrode has negligible contact resistance, which reduces thermal resistance of the thermoelectric cooler as compared to current-technology thermoelectric coolers having solder bonding layers. Accordingly, the thermoelectric cooler having a solderless electrode may be incorporated in a semiconductor package to effectively cool hot spots on an IC die.

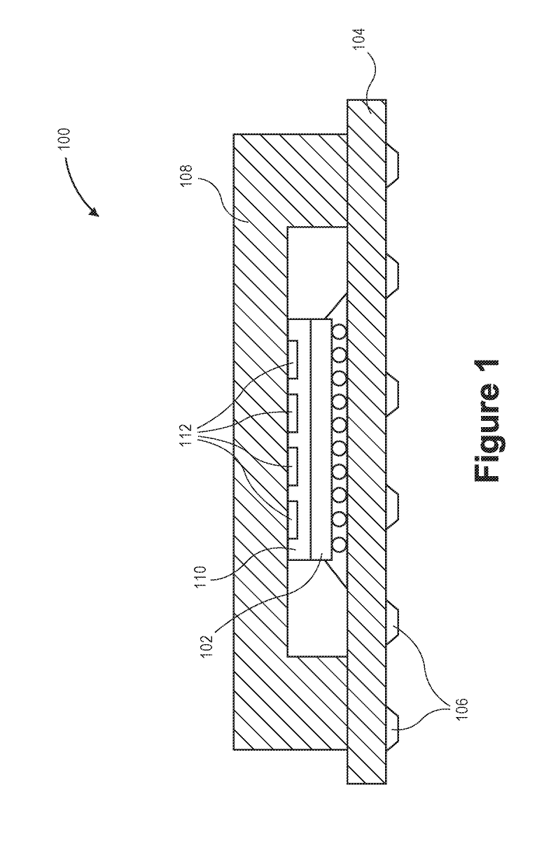

Referring to FIG. 1, a sectional view of a semiconductor package including thermoelectric coolers is illustrated in accordance with an embodiment. Semiconductor package 100 includes an IC die 102, e.g., a logic die such as a CPU die or a memory die, mounted on a package substrate 104. More particularly, die pins, such as I/O pins or power pins of die 102, may be electrically connect to contact pads 106, e.g., a ball grid array, mounted on package substrate 104. Such electrical connections may include vias, interconnects, or other known electrical connections. Thus, semiconductor package 100 may be mounted on, and interface with external circuitry of, a printed circuit board such as a motherboard.

Operation of die 102 may generate heat, and thus, semiconductor package 100 may include an integrated heat spreader 108 to dissipate heat from die 102. For example, integrated heat spreader 108 may be a nickel-coated copper sheet thermally connected to die 102 to conduct heat away from die 102. In an embodiment, integrated heat spreader 108 is mounted on package substrate 104, and forms a top case of semiconductor package 100. Thus, die 102 may be mounted on package substrate 104 between integrated heat spreader 108 and package substrate 104. Thermal contact between integrated heat spreader 108 and die 102 may be facilitated by a thermal interface material 110. Thermal interface material 110 may be an intermediate layer that conducts heat between die 102 and integrated heat spreader 108. For example, thermal interface material 110 may be a polymer and/or filled-polymer material having good heat transfer properties. Heat transfer from integrated heat spreader 108 to the surrounding environment may be aided by forced air cooling of a heat sink (not shown) that is mounted on, and thermally connected to, integrated heat spreader 108.

Integrated heat spreader 108 may have a generalized cooling effect on die 102. More particularly, the heat transfer provided by integrated heat spreader 108 may not preferentially cool any local portion of die 102 more than another portion by design. Thus, as electronics within subareas of a die surface are utilized for specific processing operations, hot spots may arise within the subareas. Accordingly, one or more thermoelectric cooler 112 may be distributed across the die surface to locally cool such hot spots. For example, several thermoelectric coolers 112 may be mounted on die 102 and/or thermal interface material 110 in a grid pattern. Alternatively, thermoelectric coolers 112 may be mounted on die 102 at predetermined locations that are known to be hot spots during die operation. In an embodiment, thermoelectric coolers 112 are mounted between die 102 and integrated heat spreader 108. For example, thermoelectric cooler 112 may be in direct contact with integrated heat spreader 108, and thermal interface material 110 may physically separate, but thermally connect, die 102 to thermoelectric cooler 112.

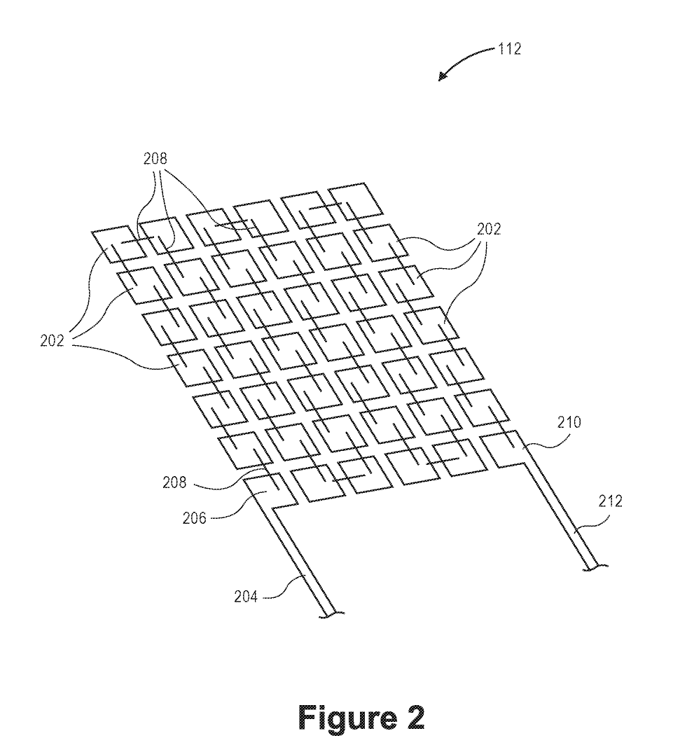

Referring to FIG. 2, a thermoelectric cooler having interconnected P-N elements is illustrated in accordance with an embodiment. Each thermoelectric cooler 112 may include several P-N elements 202 electrically connected in series between an input and an output lead. For example, P-N elements 202 of thermoelectric cooler 112 may be arranged in a grid pattern having rectangular dimensions. By way of example, thermoelectric cooler 112 may have overall dimensions of 3 by 3.5 millimeters. Thus, thermoelectric cooler 112 may have a footprint to locally cool a subregion on die 102 having similar dimensions, e.g., 3 by 3.5 millimeters. It will be noted, however, that the thermoelectric cooler footprint may include any size or shape, according to the number and arrangement of P-N elements 202.

Each thermoelectric cooler 112 may receive electrical current from an input voltage lead 204 electrically connected to an external power source. For example, input voltage lead 204 may electrically connect to a first P-N element 206 of thermoelectric cooler 112. An architecture of each P-N element 202 is described further below. By way of summary, however, each P-N element 202 may essentially include a pair of semiconductor columns, and each semiconductor column may include a respective semiconductor layer, e.g., a P-type semiconductor layer and an N-type semiconductor layer. The semiconductor columns within a P-N element 202 may be electrically connected to each other, e.g., by an electrode. Furthermore, each P-N element 202 in thermoelectric cooler 112 may be electrically connected to one or more adjacent P-N element 202, e.g., by an interconnect 208. For example, first P-N element 206 may be electrically connected to a subsequent P-N element 202 by interconnect 208, and several other P-N elements 202 may be connected by respective interconnects 208 in the same electrical series leading to a last P-N element 210 of thermoelectric cooler 112.

In an embodiment, each N-type semiconductor layer is electrically connected to a P-type semiconductor layer in an adjacent P-N element 202, and each P-type semiconductor layer in a P-N element 202 is electrically connected to an N-type semiconductor layer in an adjacent P-N element 202. Thus, electrical current may propagate from P-type semiconductor layers to N-type semiconductor layers to P-type semiconductor layers and so on, until leaving thermoelectric cooler 112 from last P-N element 210 to an output voltage lead 212. The electrical current may continue to another serially connected thermoelectric cooler 112, or to the external power source to complete a power circuit.

Thermoelectric cooler 112 may be an active device. More particularly, delivery of the electrical current through the serially connected P-N elements 202 may generate a cooling effect on one side of thermoelectric cooler 112. The semiconductor columns may extend between a hot-side, e.g., a side facing integrated heat spreader 108 and a cold-side, e.g., a side facing die 102. The electrical current passes in a first direction through the P-type semiconductor layer, e.g., in a direction from die 102 to integrated heat spreader 108, and in an opposite direction through the N-type semiconductor layer, e.g., in a direction from integrated heat spreader 108 to die 102. Based on the well-known Peltier Effect, a heat flux is generated to transfer heat from the cold-side to the hot-side of thermoelectric cooler 112. In an embodiment, a direction of the electrical current may be reversed to change a direction of heat transfer, but in general, P-N elements 202 may be arranged and operated to transfer heat from die 102 to integrated heat spreader 108.

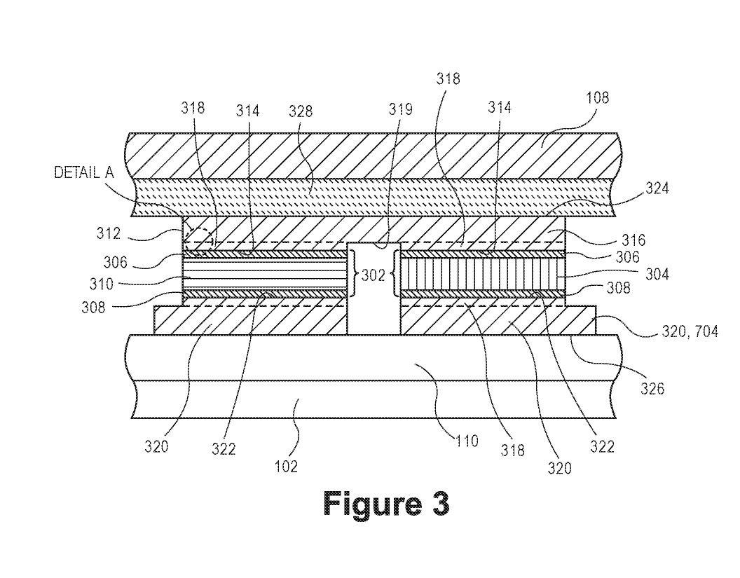

Referring to FIG. 3, a sectional view of a P-N element of a thermoelectric cooler having solderless electrical interconnects is illustrated in accordance with an embodiment. As described above, each P-N element 202 of a thermoelectric cooler 112 may include a pair of semiconductor columns 302. For example, a first semiconductor column 302 may include a P-type semiconductor layer 304 sandwiched between a respective hot-side diffusion barrier layer 306 and a respective cold-side diffusion barrier layer 308. A second semiconductor column 302 of the P-N element 202 may include an N-type semiconductor layer 310 sandwiched between a respective hot-side diffusion barrier layer 306 and a respective cold-side diffusion barrier layer 308. As described above, thermoelectric cooler 112 may cool die 102 by transferring heat from die 102 (or thermal interface material 110) to integrated heat spreader 108. Thus, by way of convention, components of thermoelectric cooler 112 between the semiconductor columns 302 and die 102 may be referred to as “cold-side” components, e.g., cold side diffusion barrier layers 308, and components of thermoelectric cooler 112 between the semiconductor columns 302 and integrated heat spreader 108 may be referred to as “hot-side” components, e.g., hot side diffusion barrier layers 306.

In an embodiment, the diffusion barrier layers may separate the semiconductor material of P-type semiconductor layer 304 and N-type semiconductor layer 310 from adjacent electrodes or interconnects. More particularly, each diffusion barrier layer may prevent diffusion of material from the adjacent electrodes or interconnects into the semiconductor material. For example, each diffusion barrier layer may include nickel, to prevent diffusion of copper from the adjacent electrical connections into the P-type semiconductor material or N-type semiconductor material of respective semiconductor columns 302.

In an embodiment, semiconductor columns 302 of P-N element 202 are electrically connected by a solderless electrode 312. More particularly, solderless electrode 312 may electrically connect P-type semiconductor material of P-type semiconductor layer 304 to N-type semiconductor material of N-type semiconductor layer 310. Solderless electrode 312 may be a copper electrode 702 having a contact surface 314 in contact with hot-side diffusion barrier layer 306 of an N-type semiconductor column 302, and contact surface 314 in contact with hot-side diffusion barrier layer 306 of a P-type semiconductor column 302. Thus, copper of solderless electrode 312 may be separated from respective N-type or P-type semiconductor materials of the pair of semiconductor columns 302 only by the respective hot side diffusion barrier layers 306.

In an embodiment, solderless electrode 312 may be formed in a process that provides it with a particular morphology. More particularly, solderless electrode 312 may include a bridge portion 316 extending laterally from a location above N-type semiconductor layer 310 to a location above P-type semiconductor layer 304. Furthermore, solderless electrode 312 may include several contact portions 318 above respective semiconductor columns 302. That is, each contact portion 318 may protrude from bridge portion 316 to a respective one of contact surfaces 314.

Contact portions 318 of solderless electrode 312 may be laterally offset from a bottom surface 319 of bridge portion 316. For example, each contact portion 318 may extend from bottom surface 319, and/or a plane that is coplanar with bottom surface 319, to the respective one of contact surfaces 314. Thus, contact surfaces 314 may be laterally spaced apart from each other, and may also be spaced apart from bottom surface 319 in a direction orthogonal to bottom surface 319. More generally, contact portions 318 may be referred to as boss portions or bulges connected to bridge portion 316 at the dashed line illustrated in FIG. 3. Accordingly, each P-N element 202 of thermoelectric cooler 112 may include an electrical path between N-type semiconductor layer 310 and P-type semiconductor layer 304, which extends directly from the P-type semiconductor material through a diffusion barrier layer into a solderless electrode, and from the solderless electrode through another diffusion barrier layer into the N-type semiconductor material.

In an embodiment, an electrical interconnection between a P-N element 202 and an adjacent P-N element 202 may be similar to the electrical interconnection between P-type semiconductor layer 304 and N-type semiconductor layer 310 within P-N element 202. More particularly, each semiconductor layer of the pair of semiconductor columns 302 may be separated from a solderless interconnect 320 by a diffusion barrier layer. For example, cold-side diffusion barrier layer 308 of the P-type semiconductor column 302 may separate P-type semiconductor layer 304 from solderless interconnect 320. Accordingly, an interconnect surface 322 of solderless interconnect 320 may be in direct contact with cold-side diffusion barrier layer 308 of the P-type semiconductor column 302. Similarly, cold-side diffusion barrier layer 308 of the N-type semiconductor column 302 may separate N-type semiconductor layer 310 from a respective solderless interconnect 320. Accordingly, a respective interconnect surface 322 of the respective solderless interconnect 320 may be in direct contact with cold-side diffusion barrier layer 308 of the N-type semiconductor column 302.

Each solderless interconnect 320 may include portions having a morphology similar to portions of solderless electrode 312. For example, solderless interconnect 320 may include contact portion 318 extending from an interconnect lead toward the respective diffusion barrier layer. Accordingly, an electrical current passing between adjacent P-N elements 202 via interconnect 208 of thermoelectric cooler 112 may travel from a semiconductor layer through a diffusion barrier layer directly into solderless interconnect 320. In an embodiment, solderless interconnect 320 is a copper interconnect, and thus, copper of solderless interconnect 320 may be separated from semiconductor material of the semiconductor layer only by cold-side diffusion barrier layer 308.

Implementation of thermoelectric cooler 112 having solderless electrode 312 and solderless interconnect 320 may reduce a height of thermoelectric cooler 112. For example, a distance between solderless electrode 312 and solderless interconnect 320 may be less than a corresponding distance in a thermoelectric cooler 112 that includes solder bonds between the electrode and the diffusion barrier layers. More particularly, it has been shown that an orthogonal distance along an axis passing perpendicular to bottom surface 319 between a top surface 324 of bridge portion 316 and a base surface 326 of solderless interconnect 320 may be formed to be less than 100 microns, e.g., less than 50 microns, using the methods described below.

A reduction in height of thermoelectric cooler 112 may also be described in relation to surrounding structures of semiconductor package 100. For example, solderless electrode 312 may be mounted between the pair of semiconductor columns 302 and integrated heat spreader 108, and have a pair of contact surfaces 314 in contact with respective hot side diffusion barrier layers 306 of the pair of semiconductor columns 302. Similarly, solderless interconnects 320 may be mounted between respective semiconductor columns 302 and die 102, and have respective interconnect surfaces 322 in contact with respective cold side diffusion barrier layers 308 of respective ones of the semiconductor columns 302. As described above, thermal interface material 110 may be disposed between solderless interconnects 320 and die 102. Furthermore, in an embodiment, a dielectric layer 328 is disposed between solderless electrode 312 and integrated heat spreader 108. The dielectric layer 328 may, for example, include a dielectric material to isolate integrated heat spreader 108 from electrical current passing through thermoelectric cooler 112. Accordingly, an orthogonal distance along an axis passing perpendicular to bottom surface 319 between dielectric layer 328 and thermal interface material 110 may be less than 100 microns, e.g., less than 50 microns.

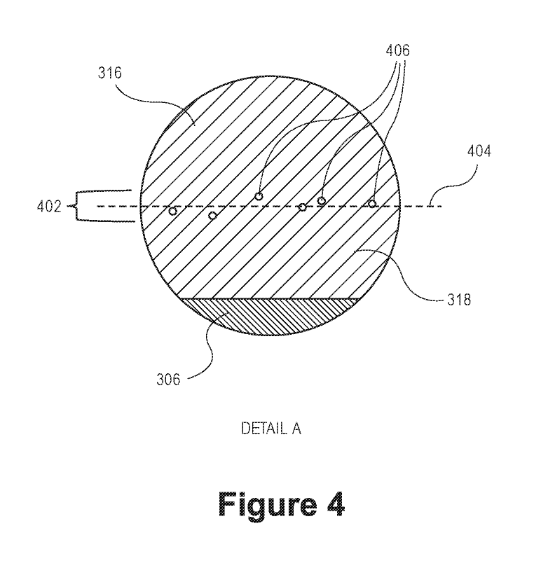

Referring to FIG. 4, a detail view, taken from FIG. 3, of a copper joint of a solderless electrode of a thermoelectric cooler is illustrated in accordance with an embodiment. The morphology of solderless electrode 312 and/or solderless interconnects 320, which includes contact portions 318 extending into direct contact with respective diffusion barrier layers, may result from forming a copper joint 402 between contact portion 318 and a lateral portion of the electrode or interconnect. For example, solderless electrode 312 may include copper joint 402 between a copper contact portion 318 and a copper bridge portion 316. The copper joint 402 may be formed using a method as described below. By way of example, contact portion 318 may initially be a copper layer of a semiconductor column precursor that is bonded to a copper electrode. The bonding may occur along the adjoining surfaces of the precursor materials, and thus, copper joint 402 may extend along plane 404 parallel to the adjoining surfaces. In an embodiment, the adjoining surface of bridge portion 316 may be bottom surface 319, such that copper joint 402 extends along a plane 404 parallel to bottom surface 319.

Contact portion 318 and bridge portion 316 of solderless electrode 312 may include similar materials, e.g., copper, and as a result, the contact resistance may be reduced as compared to a solder bond between those portions. That is, copper joint 402 may essentially have no interface between contact portion 318 and bridge portion 316, and thus, contact resistance may be minimized. Accordingly, copper joint 402 of solderless electrode 312 and/or solderless interconnect 320 may reduce thermal resistance of thermoelectric cooler 112. Nonetheless, contact portion 318 and bridge portion 316 may have some discernible separation along plane 404. For example, one or more interstices 406 may be distributed along plane 404 between bridge portion 316 and contact portions 318. Interstices 406 may result from an incomplete joint at the solderless connection. For example, in an embodiment of the method described below, low temperatures may be used to bond the portions of solderless electrode 312 such that functionality of thermoelectric cooler 112 is not adversely affected by the manufacturing process. As a result of the low temperatures processing, however, a solderless joint may be formed that includes several inclusions such as interstices 406 along plane 404. A number or density of such interstices 406 may vary from electrode to electrode of thermoelectric cooler 112. Nonetheless, in an embodiment, thermoelectric cooler 112 includes at least one interstice 406 along plane 404 between bridge portion 316 and contact portion 318.

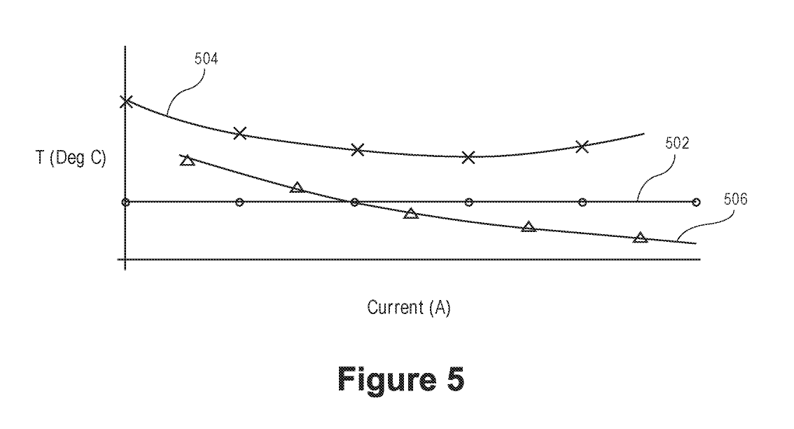

Referring to FIG. 5, a graph indicating cooling performances of various semiconductor package designs is illustrated in accordance with an embodiment. The graph plots a temperature of a hot spot of a typical high power-density semiconductor package 100 at various electrical current operating points of a representative die. By way of example, a plot line 502 represents a semiconductor package 100 without a thermoelectric cooler and having the representative die powered at a reference power of a certain amount. It can be seen that the die temperature remains approximately 100 degrees Celsius, indicating that the cooling effect of integrated heat sink remains constant at that operating point. By contrast, a plot line 504 represents a semiconductor package 100 having a current-technology thermoelectric cooler, i.e., a thermoelectric cooler that includes solder bonds. Plot line 504 shows that, at the operating point of the representative die, e.g., at the reference power, the hot spot temperature actually increases as compared to a semiconductor package 100 having only an integrated heat spreader 108, i.e., as compared to plot line 502. This reduction in performance is due in part to an increased thickness and contact resistance of the solder bonds.

Plot line 506 represents semiconductor package 100 having thermoelectric cooler 112 with solderless electrode 312 and/or solderless interconnects 320. It can be seen that the die temperature at the operating point of the representative die decreases as additional current is delivered to thermoelectric cooler 112. More particularly, as the electrical current delivered to thermoelectric cooler 112 increases, the cooling of die hot spots increases. It has thus been shown that a thermoelectric cooler architecture incorporating solderless electrodes 312 and solderless interconnects 320 may reduce the die temperature below the baseline temperature provided by a semiconductor package 100 having only an integrated heat spreader 108. Thus, the solderless architecture of thermoelectric cooler 112 can effectively cool die hot spots, e.g., on CPU dies.

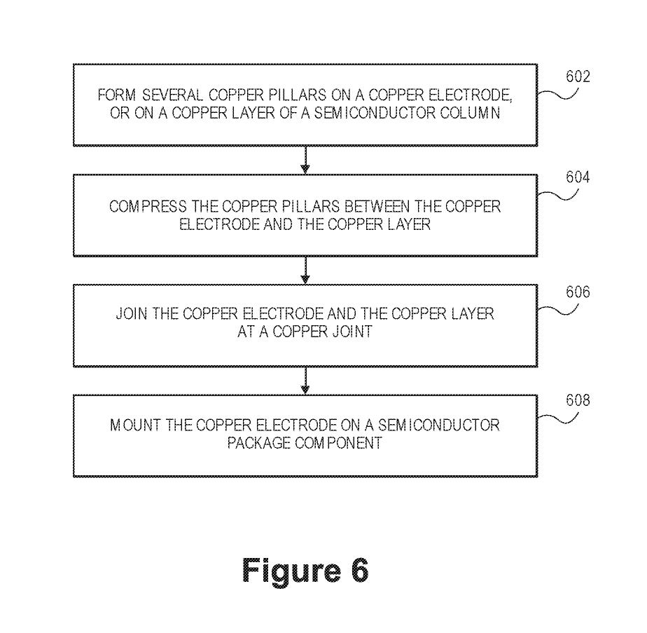

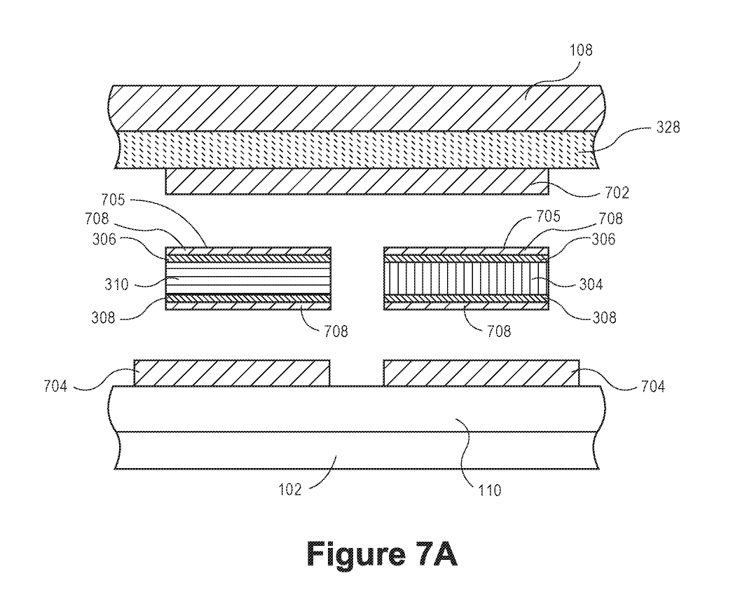

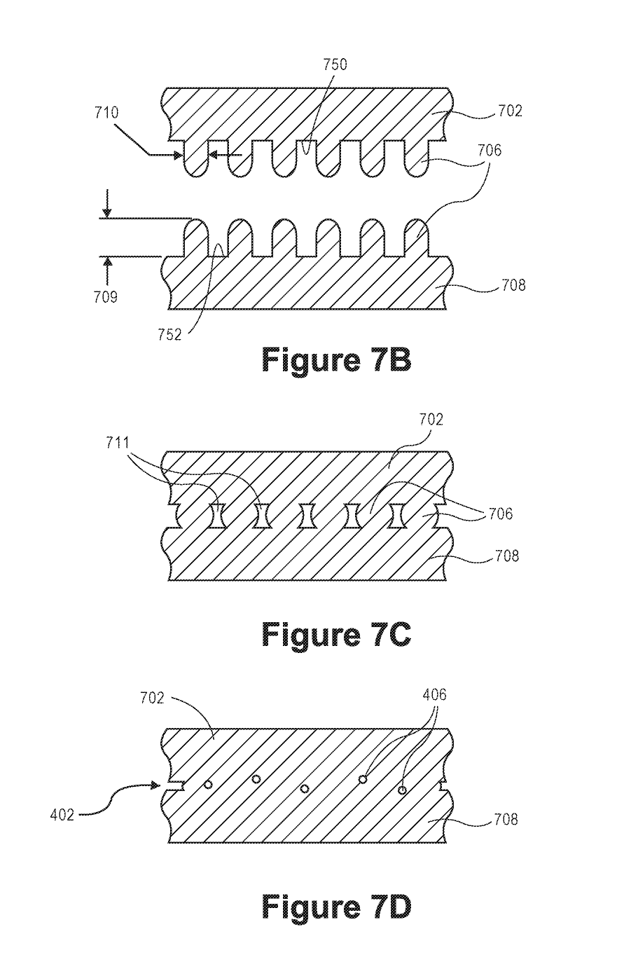

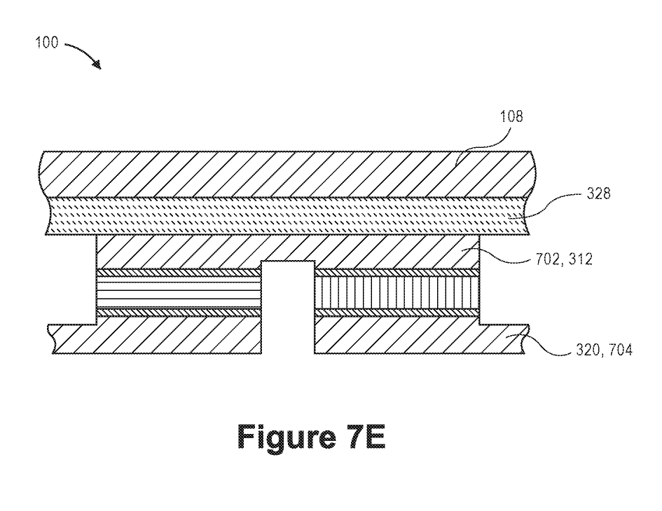

Referring to FIG. 6, a method of manufacturing a semiconductor package including a thermoelectric cooler having a solderless electrical interconnect is illustrated in accordance with an embodiment. FIGS. 7A-7E illustrate various operations in the method described in FIG. 6, and thus, the figures are described in combination below.

Referring to FIG. 7A, precursor components of a thermoelectric cooler 112 may include a copper electrode 702, one or more copper interconnects 704, and a pair of semiconductor stacks 705. Here, the term “semiconductor stack” may distinguish the precursor component from a semiconductor column 302 of a completely formed thermoelectric cooler 112. More particularly, each semiconductor stack 705 may include a respective one of P-type semiconductor layer 304 or N-type semiconductor layer 310 sandwiched between respective hot side diffusion barrier layers 306 and cold side diffusion barrier layers 308. Furthermore, each semiconductor stack 705 may include a copper layer 708 mounted on a respective diffusion barrier layer. For example, each copper layer 708 may be plated on a corresponding nickel diffusion barrier layer. It will be understood then, with reference to FIG. 3, copper electrode 702 may be a precursor component of bridge portion 316 of solderless electrode 312, copper interconnect 704 may be a precursor component of solderless interconnect 320, and copper layer 708 may be a precursor component of contact portion 318 of solderless electrode 312 or solderless interconnect 320.

As shown in FIG. 7A, one or more of the precursor components of thermoelectric cooler 112 may be mounted on other semiconductor package 100 components prior to forming thermoelectric cooler 112. For example, copper electrode 702 may be mounted on dielectric layer 328 and/or integrated heat spreader 108, and copper interconnect 704 may be mounted on thermal interface material 110 and/or die 102. Alternatively, thermoelectric cooler 112 may be mounted on a semiconductor package 100 component after completion, as described below.

Referring to FIG. 7B, at operation 602, several copper pillars 706 may be formed on copper electrode 702, or on copper layer 708. More particularly, copper pillars 706 may be formed on one of the surfaces but not on another one of the surfaces. For example, copper pillars 706 may be formed on a surface of copper electrode 702 corresponding to bottom surface 319 of solderless electrode 312. Alternatively or in addition, copper pillars 706 may be formed on a hot-side surface of copper layer 708 corresponding to the interface between bridge portion 316 and contact portion 318 of solderless electrode 312. Thus, FIG. 7B shows that copper pillars 706 may be formed on a first facing surface 750 of copper electrode 702 and a second facing surface 752 of copper layer 708, however, this is illustrative rather than restrictive. For example, copper pillars 706 may be formed on first facing surface 750 of copper electrode 702 and may not be formed on second facing surface 752 of copper layer 708. Likewise, copper pillars 706 may not be formed on first facing surface 750 of copper electrode 702 and may be formed on second facing surface 752 of copper layer 708. Accordingly, several options for forming copper pillars 706 as precursors to copper joint 402 may be used.

Patterning of copper pillars 706 on copper electrode 702 or copper layer 708 may be performed using known processes. For example, copper pillars 706 may be formed by conventional plating techniques to plate a copper material into a pillar structure on the corresponding substrate. A shape and size of the pillar structure may vary. For example, in an embodiment the pillar structure is cylindrical, however, this is not restrictive. The pillar structure may be sized on a nanometer size range. For example, copper pillars 706 may have a height 709 of less than 5 microns, e.g., less than 1 micron. Similarly, a cross-sectional dimension 710, e.g., a diameter of a cylindrical pillar 706, may be less than 1 micron, e.g., less than 100 nanometers. In an embodiment, copper pillars 706 extend perpendicular to the substrate surface, i.e., orthogonal to copper electrode 702 or copper layer 708. Copper pillars 706 may, however, extend in a non-perpendicular direction from the substrate surface, e.g., diagonally at an angle to copper electrode 702 or copper layer 708.

Referring to FIG. 7C, at operation 604, copper pillars 706 may be compressed between copper electrode 702 and copper layer 708. For example, the layers may be brought together to squeeze copper pillars 706 between their respective surfaces. As such, copper electrode 702 may be pressed against copper layer 708 with some pressure, although the range of such pressure may vary widely. In an embodiment, the pressure applied between copper electrode 702 and copper layer 708 is sufficient to cause copper pillars 706 to deform. For example, copper pillars 706 may bend or bulge, which may create several voids 711 between the pillars 706.

Referring to FIG. 7D, at operation 606, copper electrode 702 and copper layer 708 may be joined together at copper joint 402. More particularly, copper pillars 706 may be squeezed between copper electrode 702 and copper layer 708 at an elevated temperature to cause the copper material to coalesce and form copper joint 402. Copper joint 402 may correspond to the joints between bridge portion 316 and contact portion 318 of solderless electrode 312 (FIG. 4). Thus, copper joint 402 may extend along plane 404. It shall be understood that plane 404 may pass through copper pillars 706, and more particularly, through interstices 406 formed between copper pillars 706, copper electrode 702, and copper layer 708.

In an embodiment, interstices 406 result from an incomplete joint between copper electrode 702 and copper layer 708. For example, copper electrode 702 and copper layer 708 may be joined by heating copper pillars 706 to a temperature in a range of 200-300 degrees Celsius. Such temperature may be sufficient to reflow copper pillars 706 and to form copper joint 402, but may be insufficient to completely eliminate any space between the copper precursor layers 702, 708. Thus, several interstices 406 may remain along plane 404. Nonetheless, a thermal resistance of copper joint 402 having interstices 406 may be substantially less than a thermal resistance of a solder bond of a current-technology thermoelectric cooler.

Although the operations described above have been explicitly directed to forming solderless electrode 312 of thermoelectric cooler 112, it will be understood that similar operations may be used to form solderless interconnect 320 of thermoelectric cooler 112. For example, copper pillars 706 may be squeezed between respective semiconductor stacks 705 and corresponding copper interconnects 704 at an elevated temperature to form solderless interconnect 320 of thermoelectric cooler 112. Thus, operations corresponding to the formation of solderless electrode 312 may be equally applicable to formation of solderless interconnects 320 of thermoelectric cooler 112.

Referring to FIG. 7E, at operation 608, copper electrode 702 or copper interconnect 704 may be mounted on a corresponding semiconductor package 100 component. For example, copper electrode 702 corresponding to solderless electrode 312 of thermoelectric cooler 112 may be mounted on dielectric layer 328 and/or integrated heat spreader 108 of semiconductor package 100. Similarly, copper interconnect 704 corresponding to solderless interconnect 320 of thermoelectric cooler 112 may be mounted on thermal interface material 110 and/or die 102 of semiconductor package 100 (not shown). Accordingly, semiconductor package 100 including thermoelectric cooler 112 having solderless electrode 312 and/or solderless interconnect 320 may be provided.

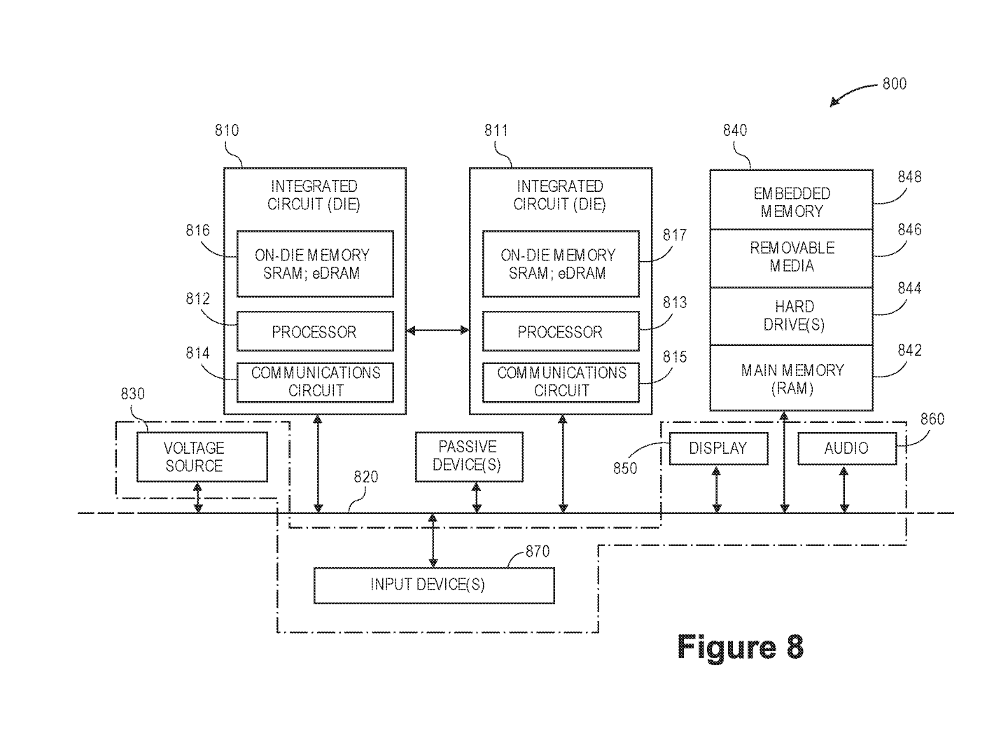

Referring to FIG. 8, a schematic of a computer system is illustrated in accordance with an embodiment. The computer system 800 (also referred to as the electronic system 800) as depicted can embody semiconductor packages including thermoelectric coolers having solderless electrical interconnects, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, semiconductor packages including thermoelectric coolers having solderless electrical interconnects, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 811 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, and an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a semiconductor package including a thermoelectric cooler having solderless electrical interconnects, according to any of the several disclosed embodiments and their equivalents, an electronic system, a computer system, one or more methods of fabricating an integrated circuit, and one or more methods of fabricating a semiconductor package including a thermoelectric cooler having solderless electrical interconnects, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor packages including thermoelectric coolers having solderless electrical interconnects embodiments and their equivalents. A foundation substrate may be included, as represented by the dashed line of FIG. 8. Passive devices may also be included, as is also depicted in FIG. 8.

In an embodiment, a thermoelectric cooler includes a first semiconductor column having a P-type semiconductor layer between a first hot-side diffusion barrier layer and a first cold-side diffusion barrier layer. The thermoelectric cooler includes a second semiconductor column having an N-type semiconductor layer between a second hot-side diffusion barrier layer and a second cold-side diffusion barrier layer. The thermoelectric cooler includes a solderless electrode electrically connecting the P-type semiconductor layer to the N-type semiconductor layer. The solderless electrode includes a first contact surface in contact with the first hot-side diffusion barrier layer and a second contact surface in contact with the second hot-side diffusion barrier layer.

In one embodiment, the solderless electrode includes a bridge portion and several contact portions. Each contact portion protrudes from the bridge portion to a respective one of the contact surfaces.

In one embodiment, each contact portion extends from a bottom surface of the bridge portion to the respective one of the contact surfaces. The contact surfaces are spaced apart from the bottom surface in a direction orthogonal to the bottom surface.

In one embodiment, the solderless electrode includes a copper joint between the bridge portion and the contact portions. The copper joint extends along a plane parallel to the bottom surface.

In one embodiment, the solderless electrode includes several interstices distributed along the plane between the bridge portion and the contact portions.

In one embodiment, the thermoelectric cooler further includes a first solderless interconnect having a first interconnect surface in contact with the first cold-side diffusion barrier layer. The thermoelectric cooler includes a second solderless interconnect having a second interconnect surface in contact with the second cold-side diffusion barrier layer.

In one embodiment, an orthogonal distance between the solderless electrode and the first solderless interconnect is less than 50 microns.

In an embodiment, a semiconductor package includes an integrated heat spreader mounted on a package substrate. The semiconductor package includes a die mounted between the integrated heat spreader and the package substrate. The semiconductor package includes a thermoelectric cooler mounted between the die and the integrated heat spreader. The thermoelectric cooler includes a pair of semiconductor columns, each semiconductor column including a respective semiconductor layer between a respective hot-side diffusion barrier layer and a respective cold-side diffusion barrier layer. The thermoelectric cooler includes a solderless electrode mounted between the semiconductor columns and the integrated heat spreader. The solderless electrode includes a pair of contact surfaces in contact with respective hot-side diffusion barrier layers of the pair of semiconductor columns.

In one embodiment, the solderless electrode includes a bridge portion and a pair of contact portions, each contact portion protruding from the bridge portion to a respective one of the pair of contact surfaces.

In one embodiment, each contact portion extends from a bottom surface of the bridge portion to the respective one of the pair of contact surfaces. The contact surfaces are spaced apart from the bottom surface in a direction orthogonal to the bottom surface.

In one embodiment, the solderless electrode includes a copper joint between the bridge portion and the contact portions. The copper joint extends along a plane parallel to the bottom surface.

In one embodiment, the solderless electrode includes several interstices distributed along the plane between the bridge portion and the contact portions.

In one embodiment, the semiconductor package further includes a first solderless interconnect between one of the semiconductor columns and the die, the first solderless interconnect having a first interconnect surface in contact with the respective cold-side diffusion barrier layer of the one of the semiconductor columns. The semiconductor package includes a second solderless interconnect between another of the semiconductor columns and the die, the second solderless interconnect having a second interconnect surface in contact with the respective cold-side diffusion barrier layer of the another of the semiconductor columns.

In one embodiment, the semiconductor package further includes a dielectric layer between the solderless electrode and the integrated heat spreader. The semiconductor package includes a thermal interface material between the solderless interconnects and the die. An orthogonal distance between the dielectric layer and the thermal interface material is less than 50 microns.

In an embodiment, a method of manufacturing a semiconductor package including a thermoelectric cooler having a solderless electrical interconnect includes forming several copper pillars on one or more of a copper electrode, or a copper layer of a semiconductor stack. The semiconductor stack includes a diffusion barrier layer between the copper layer and a semiconductor layer. The method includes compressing the copper pillars between the copper electrode and the copper layer. The method includes joining the copper electrode and the copper layer at a copper joint. The copper joint extends along a plane passing through the copper pillars.

In one embodiment, the copper pillars have a height less than 5 microns and a cross-sectional dimension less than 1 micron.

In one embodiment, forming the copper pillars includes plating the copper pillars on one or more of the copper electrode or the copper layer.

In one embodiment, joining the copper electrode and the copper layer includes heating the copper pillars to a temperature in a range of 200-300 degrees Celsius.

In one embodiment, the copper joint includes several interstices distributed along the plane between the copper electrode and the copper layer.

In one embodiment, the method further includes mounting the copper electrode on one of an integrated heat spreader or a die of a semiconductor package.

What is claimed is:

1. A thermoelectric cooler, comprising:
a first semiconductor column including a P-type semiconductor layer between a first hot-side diffusion barrier layer and a first cold-side diffusion barrier layer;
a second semiconductor column including an N-type semiconductor layer between a second hot-side diffusion barrier layer and a second cold-side diffusion barrier layer; and
a solderless electrode electrically connecting the P-type semiconductor layer to the N-type semiconductor layer, wherein the solderless electrode includes a first contact surface in contact with the first hot-side diffusion barrier layer and a second contact surface in contact with the second hot-side diffusion barrier layer.

2. The thermoelectric cooler of claim 1, wherein the solderless electrode includes a bridge portion and a plurality of contact portions, each contact portion protruding from the bridge portion to a respective one of the contact surfaces.

3. The thermoelectric cooler of claim 2, wherein each contact portion extends from a bottom surface of the bridge portion to the respective one of the contact surfaces, and wherein the contact surfaces are spaced apart from the bottom surface in a direction orthogonal to the bottom surface.

4. The thermoelectric cooler of claim 3, wherein the solderless electrode includes a copper joint between the bridge portion and the contact portions, and wherein the copper joint extends along a plane parallel to the bottom surface.

5. The thermoelectric cooler of claim 4, wherein the solderless electrode includes a plurality of interstices distributed along the plane between the bridge portion and the contact portions.

6. The thermoelectric cooler of claim 1 further comprising:
a first solderless interconnect having a first interconnect surface in contact with the first cold-side diffusion barrier layer; and
a second solderless interconnect having a second interconnect surface in contact with the second cold-side diffusion barrier layer.

7. The thermoelectric cooler of claim 6, wherein an orthogonal distance between the solderless electrode and the first solderless interconnect is less than 50 microns.

8. A semiconductor package, comprising:
an integrated heat spreader mounted on a package substrate;
a die mounted between the integrated heat spreader and the package substrate; and
a thermoelectric cooler mounted between the die and the integrated heat spreader, wherein the thermoelectric cooler includes:
a pair of semiconductor columns, each semiconductor column including a respective semiconductor layer between a respective hot-side diffusion barrier layer and a respective cold-side diffusion barrier layer, and
a solderless electrode mounted between the semiconductor columns and the integrated heat spreader, wherein the solderless electrode includes a pair of contact surfaces in contact with respective hot-side diffusion barrier layers of the pair of semiconductor columns.

9. The semiconductor package of claim 8, wherein the solderless electrode includes a bridge portion and a pair of contact portions, each contact portion protruding from the bridge portion to a respective one of the pair of contact surfaces.

10. The semiconductor package of claim 9, wherein each contact portion extends from a bottom surface of the bridge portion to the respective one of the pair of contact surfaces, and wherein the contact surfaces are spaced apart from the bottom surface in a direction orthogonal to the bottom surface.

11. The semiconductor package of claim 10, wherein the solderless electrode includes a copper joint between the bridge portion and the contact portions, and wherein the copper joint extends along a plane parallel to the bottom surface.

12. The semiconductor package of claim 11, wherein the solderless electrode includes a plurality of interstices distributed along the plane between the bridge portion and the contact portions.

13. The semiconductor package of claim 8 further comprising:
a first solderless interconnect between one of the semiconductor columns and the die, the first solderless interconnect having a first interconnect surface in contact with the respective cold-side diffusion barrier layer of the one of the semiconductor columns; and
a second solderless interconnect between another of the semiconductor columns and the die, the second solderless interconnect having a second interconnect surface in contact with the respective cold-side diffusion barrier layer of the another of the semiconductor columns.

14. The semiconductor package of claim 13 further comprising:
a dielectric layer between the solderless electrode and the integrated heat spreader; and
a thermal interface material between the solderless interconnects and the die, wherein an orthogonal distance between the dielectric layer and the thermal interface material is less than 50 microns.

15. A method, comprising:
forming a plurality of copper pillars on one or more of a copper electrode, or a copper layer of a semiconductor stack, wherein the semiconductor stack includes a diffusion barrier layer between the copper layer and a semiconductor layer;
compressing the copper pillars between the copper electrode and the copper layer; and
joining the copper electrode and the copper layer at a copper joint, wherein the copper joint extends along a plane passing through the copper pillars.

16. The method of claim 15, wherein the copper pillars have a height less than 5 microns and a cross-sectional dimension less than 1 micron.

17. The method of claim 16, wherein forming the copper pillars includes plating the copper pillars on one or more of the copper electrode or the copper layer.

18. The method of claim 15, wherein joining the copper electrode and the copper layer includes heating the copper pillars to a temperature in a range of 200-300 degrees Celsius.

19. The method of claim 18, wherein the copper joint includes a plurality of interstices distributed along the plane between the copper electrode and the copper layer.

20. The method of claim 15 further comprising mounting the copper electrode on one of an integrated heat spreader or a die of a semiconductor package.
